(19) United States
(12) Patent Application Publication
(10) Pub. No.: US 2025/0280679 A1
(43) Pub. Date: Sep. 4, 2025

(54) DISPLAY APPARATUS

(71) Applicant: LG Display Co., Ltd., Seoul (KR)

(72) Inventors: YeSeul HAN, Gimpo-si (KR); JeongOk JO, Seoul (KR); HongSik KIM, Goyang-si (KR); EuiTae KIM, Goyang-si (KR)

(73) Assignee: LG Display Co., Ltd., Seoul (KR)

(21) Appl. No.: 19/056,035

(22) Filed: Feb. 18, 2025

(30) Foreign Application Priority Data
Feb. 29, 2024 (KR) 10-2024-0030319
Oct. 25, 2024 (KR) 10-2024-0147410

(51) Int. Cl. H10K 59/131; G09G 3/3266; H10K 59/80; H10K 77/10

(52) U.S. Cl. CPC H10K 59/131; G09G 3/3266; H10K 59/873; H10K 77/111; G09G 2330/04

(57) ABSTRACT

A display apparatus according to an example embodiment of the present disclosure includes a substrate including a display area in which a plurality of sub-pixels is disposed and a non-display area enclosing the display area, a constant voltage line disposed in the non-display area and including a plurality of openings and a plurality of electrostatic discharger disposed in the plurality of openings.

### CROSS-REFERENCE TO RELATED APPLICATIONS

This application claims the priority of Korean Patent Application No. 10-2024-0030319 filed on Feb. 29, 2024, and Korean Patent Application No. 10-2024-0147410 filed on Oct. 25, 2024, both in the Korean Intellectual Property Office, the disclosure and contents of which are incorporated herein by reference.

### BACKGROUND

### Technical Field

The present disclosure relates to a display apparatus.

### Description of the Related Art

With the advancement of technologies in the modern society, a display apparatus has been used in various forms to provide users with information. The display apparatus is also included in various electronic devices, which receive a user input and use advanced technologies to provide information in response to the received input, as well as an electronic display board that unilaterally transfers visual information.

Typical display apparatuses include a liquid crystal display (LCD) device, a field emission display (FED) device, an electro-wetting display (EWD) device, an organic light emitting display (OLED) device, and the like.

Particularly, the organic light emitting display apparatus as a self-luminous display apparatus does not require a separate light source unlike the liquid crystal display apparatus. Thus, the organic light emitting display apparatus can be manufactured lightly and thinly. Further, the organic light emitting display apparatus is not only advantageous in terms of power consumption by low voltage driving, but also has excellent color implementation, response speed, viewing angle, and contrast ratio (CR). Therefore, the organic light emitting display apparatus is utilized in various fields.

### BRIEF SUMMARY

The present disclosure provides a display apparatus with a reduced bezel.

The present disclosure provides a display apparatus which can reduce a defect caused by static electricity while securing reliability.

Technical features of the example embodiment of the present disclosure are not limited to those above-mentioned, and other technical features, which are not mentioned above, can be clearly understood by those skilled in the art from the following descriptions.

A display apparatus according to an example embodiment of the present disclosure includes a substrate including a display area in which a plurality of sub-pixels is disposed and a non-display area enclosing the display area, a constant voltage line disposed in the non-display area and including a plurality of openings and a plurality of electrostatic discharger disposed in the plurality of openings.

Other detailed matters of the example embodiments are included in the detailed description and the drawings.

According to the present disclosure, an electrostatic discharger is disposed on a constant voltage line disposed in a power area of a non-display area to reduce a bezel.

According to the present disclosure, the electrostatic discharger is disposed inside an encapsulation unit to secure reliability and reduce a defect caused by static electricity.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram illustrating a display apparatus according to an example embodiment of the present disclosure;

FIG. 2 is a plan view of the display apparatus according to an example embodiment of the present disclosure;

FIG. 3 is a cross-sectional view of a display area of the display apparatus according to an example embodiment of the present disclosure;

FIG. 4 is a schematic plan view of the display apparatus according to an example embodiment of the present disclosure;

FIG. 5 is a plan view illustrating a part of the non-display area of the display apparatus according to an example embodiment of the present disclosure;

FIG. 6 is a circuit diagram of an electrostatic discharger of the display apparatus according to an example embodiment of the present disclosure;

FIG. 7 is a plan view illustrating the electrostatic discharger of the display apparatus according to an example embodiment of the present disclosure;

FIG. 8 is a cross-sectional view taken along the line A-A′ of FIG. 5;

FIG. 9 is a cross-sectional view taken along the line B-B′ of FIG. 5;

FIG. 10 is a cross-sectional view taken along the line C-C′ of FIG. 5;

FIG. 11 is a plan view illustrating a part of a non-display area of a display apparatus according to another example embodiment of the present disclosure; and

FIG. 12 is a cross-sectional view taken along the line D-D′ of FIG. 11.

### DETAILED DESCRIPTION

Technical improvements and characteristics of the present disclosure and a method of achieving the technical improvements and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display apparatus according to example embodiments of the present disclosure will be described in detail with reference to accompanying drawings.

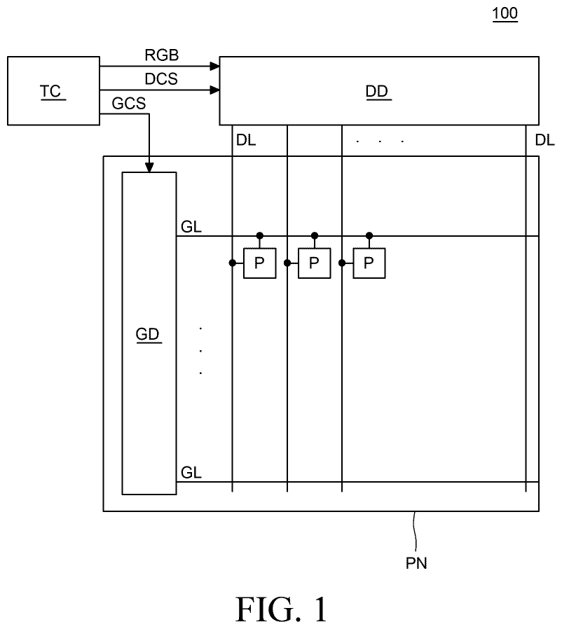

FIG. 1 is a block diagram illustrating a display apparatus according to an example embodiment of the present disclosure.

Referring to FIG. 1, a display apparatus 100 according to an example embodiment of the present disclosure includes a display panel PN, a timing controller TC, a data driver DD, and a gate driver GD.

A plurality of sub-pixels P may be disposed on the display panel PN to display images.

A plurality of gate lines GL is disposed in a first direction on the display panel PN. Also, a plurality of data lines DL is disposed in a second direction different from the first direction on the display panel PN. The plurality of gate lines GL may intersect the plurality of data lines DL, and the plurality of sub-pixels P may be disposed in a matrix form.

The plurality of sub-pixels P may be electrically connected to the plurality of gate lines GL and the plurality of data lines DL. Thus, a gate signal and a data voltage may be applied to each sub-pixel P through the gate line GL and the data line DL. Each sub-pixel P may implement a gray scale in response to the gate signal and the data voltage to display images on the display panel PN

Each of the plurality of sub-pixels P may be any one of a red sub-pixel, a green sub-pixel, a blue sub-pixel, and a white sub-pixel. The red sub-pixel, the green sub-pixel, the blue sub-pixel, and the white sub-pixel may constitute one unit pixel for color implementation. The color implemented in the unit pixel may be determined by an emission ratio of the red sub-pixel, the green sub-pixel, the blue sub-pixel, and the white sub-pixel. Meanwhile, the white sub-pixel may be omitted from the unit sub-pixel. Each of the plurality of sub-pixels P may be connected to one data line DL and one gate line GL.

The timing controller TC may transmit input image data RGB received from a host system to the data driver DD.

The timing controller TC may generate control signals GCS and DCS for controlling operation timing of the data driver DD and the gate driver GD by using timing signals received together with the image data RGB.

In other words, when the timing controller TC receives a timing signal, the timing controller TC may output a gate control signal GCS to the gate driver GD and a data control signal DCS to the data driver DD.

The data driver DD may receive the data control signal DCS and output a data voltage to the data line DL.

For example, the data driver DD may generate a sampling signal in response to the data control signal DCS and latch the image data RGB in response to the sampling signal to convert the image data RGB into a data voltage. Then, the data driver DD may apply the data voltage to the data line DL in response to a source output enable (SOE) signal.

The data driver DD may be connected to a bonding pad of the display panel PN by a Chip On Glass (COG) method or disposed directly on the display panel PN. In some embodiments, the data driver DD may be integrated and disposed on the display panel PN. Also, the data driver DD may be disposed by a Chip On Film (COF) method.

The gate driver GD may generate a scan signal and an emission signal (or emission control signal) based on the gate control signal GDC. The gate driver GD may include a scan driver and an emission signal driver. The scan driver may generate scan signals in a row sequential manner to drive at least one scan line connected to each pixel row and may supply the scan signals to the scan lines. The emission signal driver may generate emission signals in a row sequential manner to drive at least one emission signal line connected to each pixel row and may supply the emission signals to the emission signal lines.

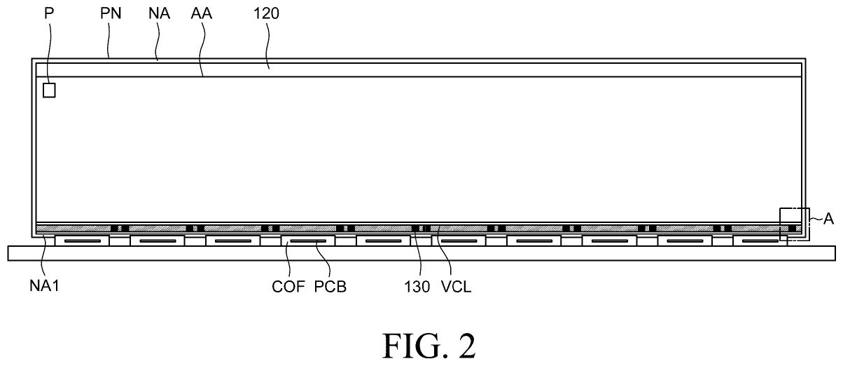

FIG. 2 is a schematic plan view of the display apparatus according to an example embodiment of the present disclosure. FIG. 2 illustrates only a plurality of flexible films COF, a printed circuit board PCB, and the display panel PN among various components of the display apparatus 100 for the convenience of description.

Referring to FIG. 2, the display apparatus 100 includes the plurality of flexible films COF, the printed circuit board PCB, and the display panel PN.

The plurality of flexible films COF may be disposed on one end of a substrate 110. The plurality of flexible films COF may be disposed on one side of the substrate 110. For example, if the substrate 110 has four sides, the plurality of flexible films COF may be spaced apart by a constant interval from each other in a longitudinal direction on one side of the display panel PN.

The plurality of flexible films COF may include various components on a flexible base film and serves to supply signals to a plurality of sub-pixels and circuits. The plurality of flexible films COF may be electrically connected to the substrate 110. For example, the plurality of flexible films COF may supply a power voltage, a gate control signal, a data voltage, etc. to the plurality of sub-pixels and driving circuits.

Meanwhile, a driver IC, such as a data driver IC, may be disposed on the plurality of flexible films COF. The driver IC is configured to process data for displaying images and a driving signal for processing the data. The driver IC may be mounted by a Chip On Glass (COG) method, a Chip On Film (COF) method, a Tape Carrier Package (TCP) method, or other similar methods. For the convenience of description, the driver IC has been described, for example, as being mounted on the plurality of flexible films COF by the COF method, but the present disclosure is not limited thereto. Alternatively, the driver IC may be integrally formed with the timing controller in a single chip. Although FIG. 2 illustrates ten flexible films COF, the number of the plurality of flexible films COF is not limited thereto. The number of the plurality of flexible films COF may be variously modified depending on design choice, such as the size of the display panel PN.

The printed circuit board PCB is electrically connected to the plurality of flexible films COF. The printed circuit board PCB is configured to supply signals to the driver IC. Various components for supplying various signals, such as a driving signal, a data signal, etc., to the driver IC may be disposed on the printed circuit board PCB. Although FIG. 2 illustrates that the plurality of flexible films COF is electrically connected to one printed circuit board PCB, the present disclosure is not limited thereto. The plurality of flexible films COF may be electrically connected to a plurality of printed circuit boards PCB, respectively.

The display panel PN is configured to display images. The display panel PN may include various circuits, lines, and light emitting diodes on the substrate. For example, the display panel PN may be divided into a display area AA and a non-display area NA.

The display area AA is configured to display images. The display area AA may include a plurality of sub-pixels P disposed in a row direction and a column direction to display images.

The non-display area NA is an area which encloses the display area AA and in which no image is displayed. Various lines for driving the plurality of sub-pixels P disposed in the display area AA are disposed in the non-display area NA. The non-display area NA may be referred to as a bezel area. A plurality of pads may be disposed in a non-display area NA1 located on one side of the display panel PN among the non-display area NA. The pads may be connected to the plurality of flexible films COF. However, the components disposed in the non-display area NA of the display panel PN are not limited thereto. Various circuits and lines may be further disposed in the non-display area NA.

A constant voltage line VCL configured to apply a constant voltage for driving to the plurality of sub-pixels P may be disposed in the non-display area NA. For example, the constant voltage line VCL may be disposed in the non-display area NA1 located on one side of the display panel PN and connected to the plurality of flexible films COF among the non-display area NA. However, the present disclosure is not limited thereto. The constant voltage line VCL may be disposed in the entire non-display area NA along the circumference of the display area AA depending on the design. The constant voltage line VCL may be any one of a high-potential power voltage line, a reference voltage line, and a low-potential power voltage line.

A plurality of electrostatic dischargers 130 may be disposed on the constant voltage line VCL.

The details thereof will be described herein.

An encapsulation unit 120 may be disposed on the display panel PN so as to cover the entire display area AA and at least a part of the non-display area NA. The encapsulation unit 120 may protect the components disposed in the display area AA and the non-display area NA from external moisture, oxygen, impacts, etc. The area in which the encapsulation unit 120 is disposed may be defined as an encapsulation area. The encapsulation unit 120 will be described in detail below.

The constant voltage line VCL may be disposed inside the encapsulation area. The constant voltage line VCL may be disposed inside the encapsulation area in which the encapsulation unit 120 is disposed. The constant voltage line VCL may be disposed more adjacent to the display area AA than an end of the encapsulation area. For example, an end on one side of the constant voltage line VCL may be disposed adjacent to the display area AA disposed inside an end of the encapsulation unit 120. Thus, the plurality of electrostatic dischargers 130 may also be disposed inside the end of the encapsulation unit 120. Accordingly, external moisture or oxygen may not permeate into the plurality of electrostatic dischargers 130, and, thus, it is possible to suppress damage, such as uniform corrosion, of the electrostatic dischargers 130.

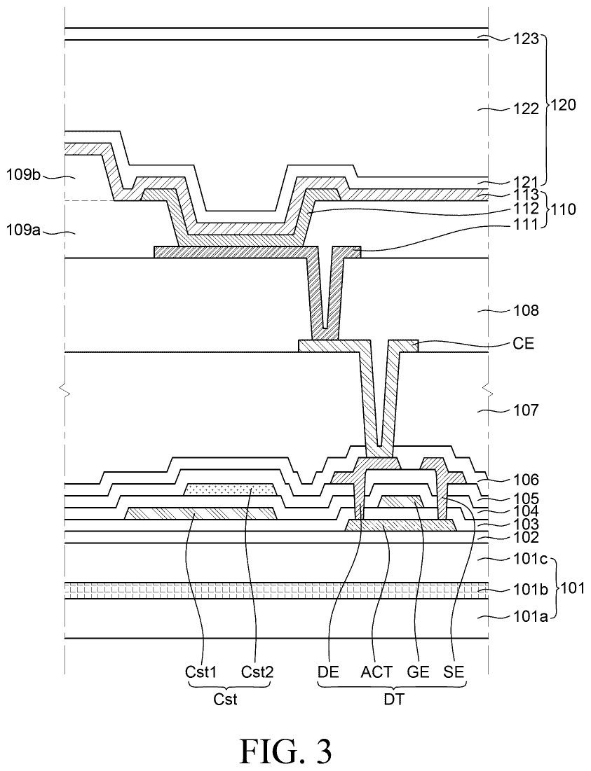

FIG. 3 is a cross-sectional view of a display area of the display apparatus according to an example embodiment of the present disclosure.

FIG. 3 illustrates only a substrate 101, a driving transistor DT, a storage capacitor Cst, a buffer layer 102, a gate insulating layer 103, a first interlayer insulating layer 104, a second interlayer insulating layer 105, a passivation layer 106, a first planarization layer 107, a second planarization layer 108, a light emitting diode 110, a bank layer 109, and the encapsulation unit 120 for the convenience of description.

Referring to FIG. 3, the display apparatus 100 according to an example embodiment of the present disclosure includes the substrate 101, the driving transistor DT, the storage capacitor Cst, and the buffer layer 102. Also, the display apparatus 100 includes the gate insulating layer 103, the first interlayer insulating layer 104, the second interlayer insulating layer 105, the passivation layer 106, and the first planarization layer 107. Further, the display apparatus 100 includes the second planarization layer 108, the light emitting diode 110, the bank layer 109, and the encapsulation unit 120.

The substrate 101 may support various components of the display apparatus 100. The substrate 101 may be made of a plastic material having flexibility. When the substrate 101 is made of a plastic material, it may be made of, for example, polyimide (PI). When the substrate 101 is made of PI, moisture may permeate through the substrate 101 made of PI to reach the driving transistor DT or the light emitting diode 110. Therefore, the performance of the display apparatus 100 may be degraded.

The display apparatus 100 according to an example embodiment of the present disclosure may be configured by two PI layers to suppress the degradation of the performance of the display apparatus 100 by moisture permeation. Further, an inorganic layer is provided between the two PI layers, and, thus, it is possible to suppress moisture permeation through the lower PI layer. Therefore, it is possible to improve the reliability of the display apparatus 100.

When the inorganic layer is provided between the two PI layers, electric charges charged in the lower PI layer may form a back bias to affect a transistor T3. A separate metal layer can be to block the electric charges charged in the PI layer. However, in the display apparatus 100 according to an example embodiment of the present disclosure, the inorganic layer is provided between the two PI layers. Thus, it is possible to block the electric charges charged in the lower PI layer. Therefore, it is possible to improve the reliability of the display apparatus 100. Further, the process of forming the metal layer to block the electric charges charged in the PI layer may be omitted. Therefore, it is possible to simplify the process and reduce the production cost.

For example, the substrate 101 of the display apparatus 100 may include a first plastic substrate 101a, a second plastic substrate 101c, and an inorganic layer 101b between the display first plastic substrate 101a and the second plastic substrate 101c. The first plastic substrate 101a may also be referred to as a first organic layer, and the second plastic substrate 101c may also be referred to as a second organic layer. When the display first plastic substrate 101a is charged with electric charges, the inorganic layer 101b may suppress the effect of the electric charges on the driving transistor DT through the second plastic substrate 101c. Further, the inorganic layer 101b provided between the display first plastic substrate 101a and the second plastic substrate 101c may suppress the permeation of moisture through the first plastic substrate 101a. The inorganic layer 101b may be configured by a single layer or a multi-layer of silicon nitride (SiNx) or silicon oxide (SiOx) but is not limited thereto.

The buffer layer 102 may be disposed on the substrate 101. The buffer layer 102 may be provided on the entire surface of the substrate 101. The buffer layer 102 may be configured by a single layer or a multi-layer of silicon nitride (SiNx) or silicon oxide (SiOx). The buffer layer 102 can reinforce adhesive strength between the layers provided on the buffer layer 102 and the substrate 101 and block alkaline components or the like flowing out of the substrate 101. Herein, the buffer layer 102 is not an essential component and may be omitted depending on the type and material of the substrate 101, the structure and type of the transistor, etc.

The driving transistor DT may be disposed on the buffer layer 102. The driving transistor DT may include an active layer ACT, a gate electrode GE, a source electrode SE, and a drain electrode DE. The active layer ACT of the driving transistor DT may be disposed on the buffer layer 102.

The active layer ACT may be made of a semiconductor material, such as an oxide semiconductor, amorphous silicon, or polysilicon, but is not limited thereto.

The gate insulating layer 103 may be disposed on the active layer ACT of the driving transistor DT. The gate insulating layer 103 may be configured by a single layer or a multi-layer of silicon nitride (SiNx) or silicon oxide (SiOx). The gate insulating layer 103 may include contact holes for connecting the source electrode SE and the drain electrode DE, respectively, of the driving transistor DT to the active layer ACT of the driving transistor DT.

The gate electrode GE of the driving transistor DT may be disposed on the gate insulating layer 103. The gate electrode GE may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof. The gate electrode GE may be disposed on the gate insulating layer 103 so as to overlap the active layer ACT of the driving transistor DT.

The first interlayer insulating layer 104 may be disposed on the gate insulating layer 103 and the gate electrode GE. The first interlayer insulating layer 104 may be configured by a single layer or a multi-layer of silicon nitride (SiNx) or silicon oxide (SiOx). The first interlayer insulating layer 104 may include contact holes for exposing the active layer ACT of the driving transistor DT.

The second interlayer insulating layer 105 may be disposed on the first interlayer insulating layer 104. The second interlayer insulating layer 105 may include contact holes for exposing the active layer ACT of the driving transistor DT. The second interlayer insulating layer 105 may be configured by a single layer or a multi-layer of silicon nitride (SiNx) or silicon oxide (SiOx).

The source electrode SE and the drain electrode DE of the driving transistor DT may be disposed on the second interlayer insulating layer 105.

The source electrode SE and the drain electrode DE of the driving transistor DT may be connected to the active layer ACT of the driving transistor DT through the contact holes formed in the gate insulating layer 103, the first interlayer insulating layer 104, and the second interlayer insulating layer 105. Therefore, the source electrode SE of the driving transistor DT may be connected to the active layer ACT through the contact hole formed in the gate insulating layer 103, the first interlayer insulating layer 104, and the second interlayer insulating layer 105. Further, the drain electrode DE of the driving transistor DT may be connected to the active layer ACT through the contact hole formed in the gate insulating layer 103, the first interlayer insulating layer 104, and the second interlayer insulating layer 105.

The storage capacitor Cst may include a first capacitor electrode Cst1 and a second capacitor electrode Cst2.

The first capacitor electrode Cst1 may be disposed on the gate insulating layer 103. The first capacitor electrode Cst1 may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof. The first capacitor electrode Cst1 may be made of the same material as the gate electrode GE but is not limited thereto.

The second capacitor electrode Cst2 may be disposed on the first interlayer insulating layer 104. The second capacitor electrode Cst2 may be disposed on the first interlayer insulating layer 104 so as to overlap the first capacitor electrode Cst1. For example, the second capacitor electrode Cst2 may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The passivation layer 106 may be disposed on the source electrode SE and the drain electrode DE of the driving transistor DT, and the second interlayer insulating layer 105. The passivation layer 106 is an insulating layer for protecting the components disposed thereunder. The passivation layer 106 may be configured by a single layer or a multi-layer of silicon nitride (SiNx) or silicon oxide (SiOx).

The first planarization layer 107 may be disposed on the passivation layer 106. The first planarization layer 107 may serve to reduce a step difference of an underlying structure. The first planarization layer 107 may be made of an organic material, such as acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

A connection electrode CE may be disposed on the first planarization layer 107. The connection electrode CE may be electrically connected to the drain electrode DE of the driving transistor DT through a contact hole formed in the passivation layer 106 and the first planarization layer 107. The connection electrode CE may be configured by a single layer of one of molybdenum (Mo), copper (Cu), titanium (Ti), aluminum (Al), chromium (Cr), gold (Au), nickel (Ni), neodymium (Nd), or an alloy thereof, or a multi-layer thereof.

The second planarization layer 108 may be disposed on the connection electrode CE and the first planarization layer 107. The second planarization layer 108 may serve to reduce a step difference of an underlying structure. The second planarization layer 108 may be made of an organic material, such as acrylic-based resin, epoxy resin, phenol resin, polyamide-based resin, polyimide-based resin, unsaturated polyester-based resin, polyphenylene-based resin, polyphenylenc sulfide-based resin, benzocyclobutene, and photoresist, but is not limited thereto.

The light emitting diode 110 may be disposed on the second planarization layer 108. The light emitting diode 110 may include a first electrode 111, an emission structure 112, and a second electrode 113. The first electrode 111 serves as an anode and may be electrically connected to the drain electrode DE of the driving transistor DT through the contact holes.

The display apparatus 100 according to an example embodiment of the present disclosure is a top-emission display apparatus. Therefore, the first electrode 111 may have a multilayer structure including a transparent conductive film and a reflective layer having a high reflection efficiency. The transparent conductive film may be made of a material having a relatively high work function, such as indium-tin-oxide (ITO) or indium-zinc-oxide (IZO). Also, the opaque conductive film may be configured by a monolayer structure, or a multilayer structure made of aluminum (Al), silver (Ag), copper (Cu), lead (Pb), molybdenum (Mo), titanium (Ti) or an alloy thereof. For example, the first electrode 111 may have a structure in which a transparent conductive film, an opaque conductive film, and a transparent conductive film are sequentially laminated. However, the present disclosure is not limited thereto. Alternatively, the first electrode 111 may have a structure in which a transparent conductive film and an opaque conductive film are sequentially laminated.

A bank layer 109a may be disposed on the first electrode 111 and the second planarization layer 108.

The bank layer 109a may include an opening for exposing the first electrode 111. The bank layer 109a defines an emission area of the display apparatus 100 with the opening and thus may serve as a pixel defining layer. For example, the bank layer 109a may be made of an organic material, such as acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

A spacer 109b may be further disposed on the bank layer 109a.

In a process of depositing the first electrode 111, the spacer 109b may serve to support a mask when the mask is aligned on the bank layer 109a. The spacer 109b may be integrally formed with the bank layer 109a. For example, the spacer 109b may be made of an organic material, such as acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The emission structure 112 may be disposed on the first electrode 111. The emission structure 112 may contain a material which can emit light of a specific color. For example, the emission structure 112 may contain a light emitting material which can emit light of any one of red, green, and blue. For example, the emission structure 112 may include at least one of a hole injection layer (HIL), a hole transport layer (HTL), an emission layer (EML), an electron transport layer (ETL), and an electron injection layer (EIL). Some of the components of the emission structure 112 may be omitted depending on the structure or characteristics of the display apparatus 100.

The second electrode 113 may be further disposed on the emission structure 112. The second electrode 113 serves as a cathode and may be disposed on the emission structure 112 so as to face the first electrode 111 with the emission structure 112 interposed therebetween. The second electrode 113 supplies electrons to the emission structure 112. For example, the second electrode 113 may be made of a conductive material having a low work function. If the display apparatus 100 is a top-emission display apparatus, the second electrode 113 may be made of transparent conductive oxide, such as indium tin oxide and indium zinc oxide, or a transparent conductive material, such as ytterbium (Yb), but is not limited thereto.

The encapsulation unit 120 for suppress moisture permeation may be further disposed on the second electrode 113.

The encapsulation unit 120 may include a first encapsulation layer 121, a second encapsulation layer 122, and a third encapsulation layer 123.

The first encapsulation layer 121 may be disposed on the second electrode 113. The first encapsulation layer 121 may be made of a transparent inorganic material which is excellent in blocking moisture permeation into the light emitting diode 110 and can be deposited at a low temperature. For example, the first encapsulation layer 121 may be made of an inorganic material, such as silicon nitride (SiNx) or silicon oxide (SiOx) but is not limited thereto.

The second encapsulation layer 122 may be disposed on the first encapsulation layer 121. The second encapsulation layer 122 is an organic layer which covers foreign matters which can be generated during the manufacturing process to compensate for any step difference caused by the foreign matters. The foreign matters generated during the manufacturing process may cause a defect of the light emitting diode 110 and also cause a crack of the inorganic layer such as the first encapsulation layer 121 or the third encapsulation layer 123. Therefore, the second encapsulation layer 122 serves to cover the crack generated by the foreign matters or compensate for the step difference caused by the foreign matters. Further, the second encapsulation layer 122 can also serve to planarize the surface on the light emitting diode 110. The second encapsulation layer 122 may be made of an organic material. For example, the second encapsulation layer 122 may be made of an organic material, such as acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The third encapsulation layer 123 may be disposed on the second encapsulation layer 122. The third encapsulation layer 123 may be made of a transparent inorganic material which is excellent in blocking moisture permeation into the light emitting diode 110 and can be deposited at a low temperature. For example, the third encapsulation layer 123 may be made of an inorganic material, such as silicon nitride (SiNx) or silicon oxide (SiOx) but is not limited thereto.

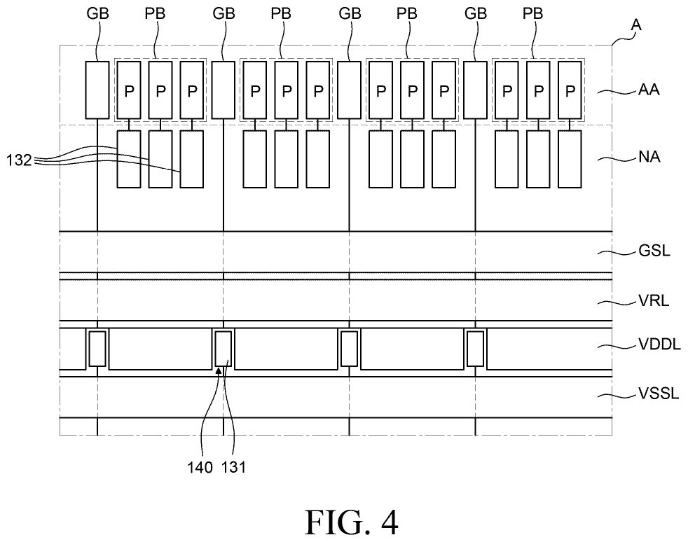

FIG. 4 is a plan view illustrating the display area and a part of a non-display area of the display apparatus according to an example embodiment of the present disclosure. FIG. 4 illustrates only a part of the display area AA, and a gate signal line GSL, a reference voltage line VRL, a high-potential power voltage line VDDL, a low-potential power voltage line VSSL, a first electrostatic discharger 131, a second electrostatic discharger 132, and openings 140 in the non-display area NA for the convenience of description.

Referring to FIG. 4, a plurality of pixel blocks PB and a plurality of gate blocks GB may be disposed in the display area AA.

The plurality of pixel blocks PB refers to an area in which a sub-pixel P is disposed and may be disposed in the column direction and the row direction in the display area AA. For example, a red sub-pixel, a green sub-pixel, and a blue sub-pixel may be disposed in the plurality of pixel blocks PB.

The plurality of gate blocks GB refers to an area in which a plurality of gate driver GD is divided and may be disposed in the column direction in the display area AA. The plurality of gate blocks GB may be disposed in parallel to the plurality of pixel blocks PB disposed in the row direction in the display area AA. The plurality of gate blocks GB may be disposed between the plurality of pixel blocks PB disposed in the row direction in the display area AA. For example, one gate driver GD may be divided into three gate blocks GB. However, the present disclosure is not limited thereto.

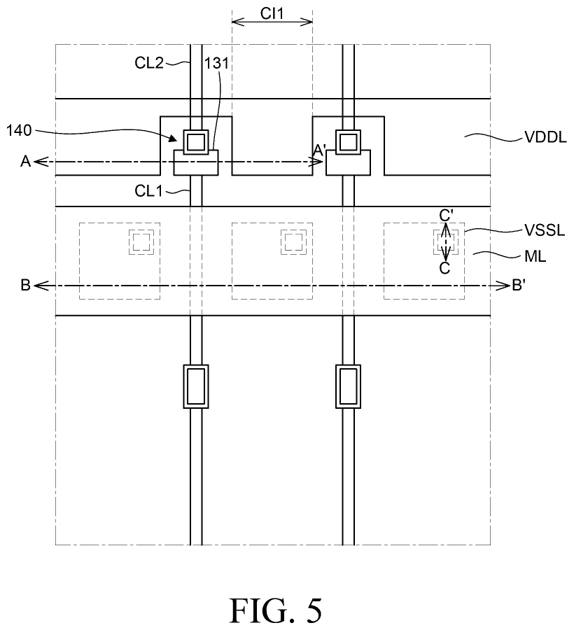

Referring to FIG. 4 and FIG. 5, the gate signal line GSL, the reference voltage line VRL, the high-potential power voltage line VDDL, and the low-potential power voltage line VSSL may be disposed in the non-display area NA.

The gate signal line GSL may transmit a gate driving signal to the plurality of gate blocks GB. For example, the gate signal line GSL may include a clock signal line for transmitting a clock signal, a gate high voltage line for transmitting a gate high voltage, and a gate low voltage line for transmitting a gate low voltage. For example, the gate signal line GSL may be disposed in the non-display area NA1 located on one side of the display panel PN connected to the plurality of flexible films COF among the non-display area NA.

The reference voltage line VRL may supply a reference voltage to the plurality of sub-pixels P. For example, the reference voltage line VRL may supply a reference voltage for operating transistors of the plurality of sub-pixels P. For example, the reference voltage line VRL may be disposed in the non-display area NA1 located on one side of the display panel PN connected to the plurality of flexible films COF among the non-display area NA.

The high-potential power voltage line VDDL may supply a high-potential power voltage to the plurality of sub-pixels P. For example, the high-potential power voltage line VDDL may supply a driving voltage for allowing light emitting diodes of the plurality of sub-pixels P to emit light. For example, the high-potential power voltage line VDDL may be disposed in the non-display area NA1 located on one side of the display panel PN connected to the plurality of flexible films COF among the non-display area NA. For example, the high-potential power voltage line VDDL may be connected to the flexible films COF.

The low-potential power voltage line VSSL may supply a low-potential power voltage to the plurality of sub-pixels P. For example, the low-potential power voltage line VSSL may supply a low-potential power voltage to the light emitting diodes of the plurality of sub-pixels P. For example, the low-potential power voltage line VSSL may be disposed in the non-display area NA1 located on one side of the display panel PN connected to the plurality of flexible films COF among the non-display area NA. For example, the low-potential power voltage line VSSL may be connected to the flexible films COF.

The plurality of electrostatic dischargers 130 may be disposed in the non-display area NA. The plurality of electrostatic dischargers 130 may discharge static electricity, which may occur or be present on the display panel PN. The plurality of electrostatic dischargers 130 may be disposed in a part of the non-display area NA corresponding to one side of the display area AA among the non-display area NA. For example, the plurality of electrostatic dischargers 130 may be disposed in the non-display area NA1 located on one side of the display panel PN and connected to the plurality of flexible films COF among the non-display area NA. Each of the plurality of electrostatic dischargers 130 may be disposed corresponding to both sides of the flexible film COF. For example, the plurality of electrostatic dischargers 130 may be disposed between the plurality of flexible films COF. The plurality of electrostatic dischargers 130 may be disposed in the area in which the constant voltage line VCL configured to apply a constant voltage is disposed. The plurality of electrostatic dischargers 130 may include a plurality of first electrostatic dischargers 131 and a plurality of second electrostatic dischargers 132.

The plurality of first electrostatic dischargers 131 may be disposed on the constant voltage line VCL. A plurality of openings 140 for exposing an underlying layer of the constant voltage line VCL may be disposed on the constant voltage line VCL. For example, the plurality of openings 140 may be disposed to be spaced apart by a constant interval CI1 from each other on the high-potential power voltage line VDDL. The plurality of openings 140 may be formed by opening one surface of the high-potential power voltage line VDDL. The plurality of openings 140 may be formed by etching a part of the high-potential power voltage line VDDL.

The plurality of first electrostatic dischargers 131 may be disposed in the plurality of openings 140, respectively. For example, the plurality of first electrostatic dischargers 131 may be disposed in the plurality of openings 140 disposed on the high-potential power voltage line VDDL. The plurality of first electrostatic dischargers 131 may be spaced apart from the high-potential power voltage line VDDL.

The plurality of first electrostatic dischargers 131 may be connected to at least one gate block GB through a gate driving signal line. Also, at least one gate block GB may be disposed to be dispersed in the display area AA, and, thus, the gate driving signal line may be disposed in the display area AA and the non-display area NA.

The plurality of first electrostatic dischargers 131 includes a plurality of transistors. When external static electricity is present at an electrode of the plurality of transistors, the static electricity may be discharged through a line connected to another electrode of the plurality of transistors. Thus, the external static electricity may not be applied to the gate driver GD. Therefore, the plurality of first electrostatic dischargers 131 may protect the gate driver GD. Further, the external static electricity may not be applied to the plurality of sub-pixels P connected to the gate driver GD. Therefore, the plurality of first electrostatic dischargers 131 may also protect the plurality of sub-pixels P.

The plurality of openings 140 and the plurality of first electrostatic dischargers 131 may be disposed corresponding to an area in which the gate driver GB is disposed. For example, the numbers of the plurality of openings 140 and the plurality of first electrostatic dischargers 131 may be equal to the number of gate blocks GB disposed in the column direction among the plurality of gate blocks GB disposed in the display area AA. For example, the number of the plurality of openings 140 and the plurality of first electrostatic dischargers 131 may be equal to the number of the plurality of gate blocks GB disposed in a row.

The plurality of second electrostatic dischargers 132 may be disposed between the display area AA and the constant voltage line VCL. For example, the plurality of second electrostatic dischargers 132 may be disposed between the display area AA and the reference voltage line VRL. The plurality of second electrostatic dischargers 132 may be connected to at least one sub-pixel P through a data line.

The plurality of second electrostatic dischargers 132 includes a plurality of transistors. When external static electricity is present at an electrode of the plurality of transistors, the static electricity may be discharged through a line connected to another electrode of the plurality of transistors. Thus, the plurality of second electrostatic dischargers 132 may protect the plurality of sub-pixels P by discharging the external static electricity which may otherwise be applied to the plurality of sub-pixels P.

FIG. 4 illustrates that the plurality of second electrostatic dischargers 132 is disposed in the non-display area NA between the display area AA and the constant voltage line VCL. However, the present disclosure is not limited thereto. A plurality of openings 140 may be further disposed between the plurality of openings 140 in which the plurality of first electrostatic dischargers 131 is disposed. Also, the plurality of second electrostatic dischargers 132 may be disposed in the plurality of openings 140 between the plurality of first electrostatic dischargers 131.

FIG. 4 illustrates that the plurality of openings 140 and the plurality of first electrostatic dischargers 131 are disposed on the high-potential power voltage line VDDL to be supplied with a high-potential power voltage. However, the present disclosure is not limited thereto. The plurality of openings 140 and the plurality of first electrostatic dischargers 131 may be disposed on the low-potential power voltage line VSSL to be supplied with a low-potential power voltage or on the reference voltage line VRL to be supplied with a reference voltage.

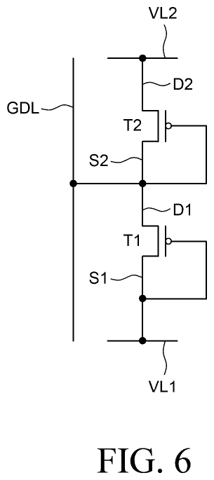

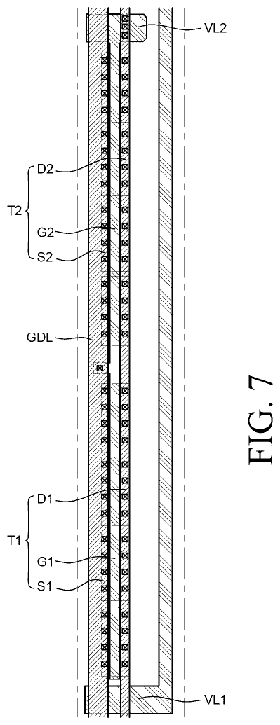

FIG. 5 is a plan view illustrating a part of the non-display area of the display apparatus according to an example embodiment of the present disclosure. FIG. 6 is a circuit diagram of an electrostatic discharger of the display apparatus according to an example embodiment of the present disclosure. FIG. 7 is a plan view illustrating the electrostatic discharger of the display apparatus according to an example embodiment of the present disclosure.

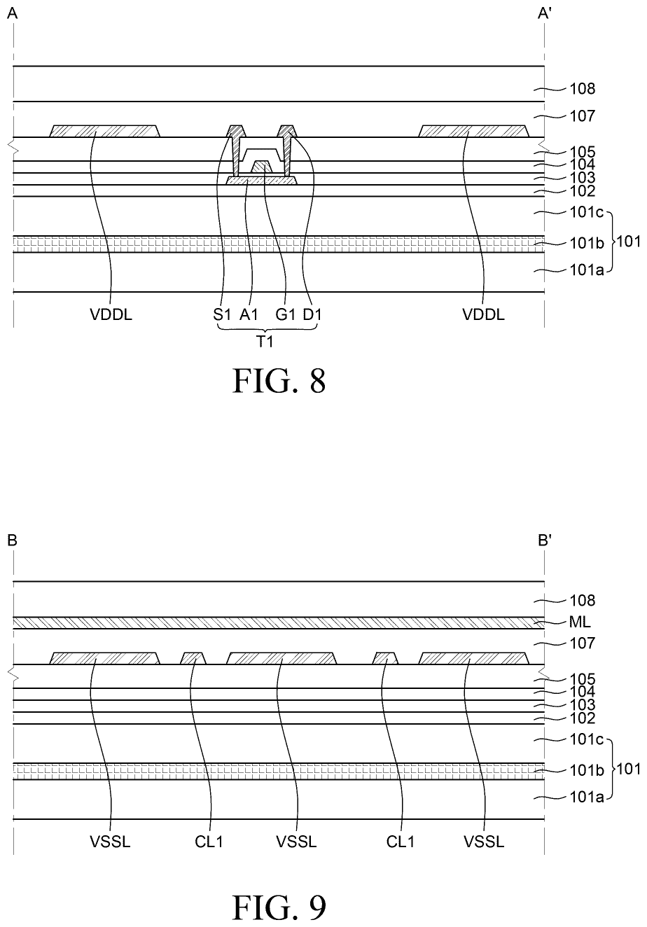

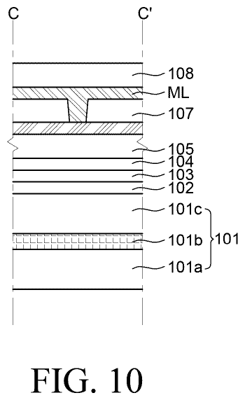

FIG. 8 is a cross-sectional view taken along the line A-A′ of FIG. 5. FIG. 9 is a cross-sectional view taken along the line B-B′ of FIG. 5. FIG. 10 is a cross-sectional view taken along the line C-C′ of FIG. 5. FIG. 5 illustrates only a part of the non-display area of the display apparatus in which the first electrostatic discharger 131 is disposed. FIG. 6 and FIG. 7 illustrate the first electrostatic discharger 131.

Referring to FIG. 5, the high-potential power voltage line VDDL may extend in the row direction in the non-display area NA. The plurality of openings 140 may be disposed to be spaced apart by a constant interval from each other on the high-potential power voltage line VDDL. For example, the plurality of openings 140 may be formed by opening one lower surface of the high-potential power voltage line VDDL. The plurality of first electrostatic dischargers 131 may be disposed in the plurality of openings 140, respectively. For example, the plurality of first electrostatic dischargers 131 may be disposed in the plurality of openings 140 disposed on the high-potential power voltage line VDDL. The plurality of first electrostatic dischargers 131 may be disposed to be spaced apart by a predetermined interval from the high-potential power voltage line VDDL.

Referring to FIG. 5 through FIG. 7, a gate driving signal line GDL extending in the column direction may be disposed in the non-display area NA. Also, a first voltage line VL1 extending in the column direction and a second voltage line VL2 extending in the column direction may be disposed in the non-display area NA. For example, the gate driving signal line GDL may be one of a clock signal line for supplying a clock signal to the gate block GB, a start signal line for supplying a start signal to the gate block GB, a gate high signal line for supplying a gate high signal to the gate block GB, and a gate low signal line for supplying a gate low signal to the gate block GB.

Referring to FIG. 6 and FIG. 7, each of the plurality of first electrostatic dischargers 131 and the plurality of second electrostatic dischargers 132 may include a first transistor T1 and a second transistor T2.

The first transistor T1 may be connected between the gate driving signal line GDL and the first voltage line VL1 to be supplied with a first voltage. For example, a first gate electrode G1 and a first source electrode S1 of the first transistor T1 may be connected to the first voltage line VL1. Also, a first drain electrode D1 of the first transistor T1 may be connected to the gate driving signal line GDL. For example, the first voltage line VL1 may be one of a low-potential voltage line to be applied with a low-potential voltage and a gate low signal line to be applied with a gate low signal.

Therefore, when a high electrostatic charge is applied to the gate driving signal line GDL, the high electrostatic charge may be input to the first drain electrode D1 of the first transistor T1. Herein, the first voltage having a low potential is applied to the first gate electrode G1 and the first source electrode S1 of the first transistor T1. Thus, a voltage equal to or higher than a breakdown voltage may be applied between the first drain electrode D1 and the first source electrode S1 of the first transistor T1. Therefore, the first transistor T1 is broken down, and the low electrostatic charge applied to the first drain electrode D1 of the first transistor T1 may be discharged through the first voltage line VL1.

The second transistor T2 may be connected between the gate driving signal line GDL and the second voltage line VL2 to be supplied with a second voltage. For example, a second gate electrode G2 and a second source electrode S2 of the second transistor T2 may be connected to the gate driving signal line GDL. Further, a second drain electrode D2 of the second transistor T2 may be connected to the second voltage line VL2. For example, the second voltage line VL2 may be one of a high-potential voltage line to be applied with a high-potential voltage and a gate high signal line to be applied with a gate high signal.

Therefore, when a low electrostatic charge is applied to the gate driving signal line GDL, the low electrostatic charge may be input to the second source electrode S2 and the second gate electrode G2 of the second transistor T2. Herein, the second voltage having a high potential is applied to the second drain electrode D2 of the second transistor T2. Thus, a voltage equal to or higher than the breakdown voltage may be applied between the second drain electrode D2 and the second source electrode S2 of the second transistor T2. Therefore, the second transistor T2 is broken down, and the low electrostatic charge applied to the second source electrode S2 of the second transistor T2 may be discharged through the first voltage line VL1.

Referring to FIG. 5 through FIG. 8, the first transistor T1 may include a first active layer A1, a first gate electrode G1, a first source electrode S1, and a first drain electrode D1.

The first active layer A1 may be disposed on the buffer layer 102. The first active layer A1 may be made of a semiconductor material, such as an oxide semiconductor, amorphous silicon, or polysilicon, but is not limited thereto.

The gate insulating layer 103 may be disposed on the first active layer A1. The gate insulating layer 103 may be configured by a single layer or a multi-layer of silicon nitride (SiNx) or silicon oxide (SiOx).

The first gate electrode G1 of the first transistor T1 may be disposed on the gate insulating layer 103. The first gate electrode G1 may be provided on the gate insulating layer 103 so as to overlap the first active layer A1. For example, the first gate electrode G1 may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The first source electrode S1 and the first drain electrode D1 of the first transistor T1 may be disposed on the second interlayer insulating layer 105. The first source electrode S1 and the first drain electrode D1 of the first transistor T1 may be connected to the first active layer A1 of the first transistor T1 through the through holes formed in the gate insulating layer 103, the first interlayer insulating layer 104, and the second interlayer insulating layer 105.

The first source electrode S1 of the first transistor T1 may be connected to the gate driving signal line GDL, and the first drain electrode D1 of the first transistor T1 may be connected to the first voltage line VL1. For example, the first source electrode S1 of the first transistor T1 may be integrally formed with the gate driving signal line GDL. Also, the first drain electrode D1 of the first transistor T1 may be integrally formed with the first voltage line VL1.

The high-potential power voltage line VDDL to be supplied with a high-potential power voltage may be disposed on the second interlayer insulating layer 105. The high-potential power voltage line VDDL may be formed of the same material on the same layer as the first source electrode S1 and the first drain electrode D1 of the first transistor T1. For example, the high-potential power voltage line VDDL may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

Referring to FIG. 5 and FIG. 9, the low-potential power voltage line VSSL may be disposed in the row direction in the non-display area NA.

The low-potential power voltage line VSSL may be disposed as a plurality of island structures spaced apart from each other. The low-potential power voltage lines VSSL may be spaced apart from each other in the row direction. The low-potential power voltage line VSSL may be disposed to be spaced apart by a predetermined interval from and parallel to the high-potential power voltage line VDDL.

The low-potential power voltage line VSSL may be disposed on the second interlayer insulating layer 105. The low-potential power voltage line VSSL may be formed of the same material on the same layer as the high-potential power voltage line VDDL. For example, the low-potential power voltage line VSSL may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The metal layer ML may be disposed on the low-potential power voltage line VSSL.

The metal layer ML may have a greater area than the low-potential power voltage line VSSL. The metal layer ML may extend in the row direction so as to overlap the low-potential power voltage line VSSL. For example, the metal layer ML may be disposed on the first planarization layer 107. The metal layer ML may be formed of the same material on the same layer as the connection electrode CE. For example, the metal layer ML may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The metal layer ML may be connected to the low-potential power voltage line VSSL through an interconnection structure. For example, referring to FIG. 10, the metal layer ML may be electrically connected to the low-potential power voltage line VSSL through a contact hole. That is, the metal layer ML may be electrically connected to the low-potential power voltage line VSSL so as to be applied with a low-potential power voltage. Thus, the metal layer ML may be applied with a low-potential power voltage and may serve as a low-potential power voltage line.

Referring to FIG. 5 and FIG. 9, a first connection line CL1 and a second connection line CL2 may be connected to each of the plurality of first electrostatic dischargers 131.

The first connection line CL1 transmits a gate driving signal and may be referred to as “gate driving signal line”. The first connection line CL1 may be connected between the plurality of first electrostatic dischargers 131 and the flexible films COF. The first connection line CL1 may extend between the low-potential power voltage lines VSSL. For example, the first connection line CL1 may extend between the low-potential power voltage lines VSSL spaced apart from each other.

The first connection line CL1 may be disposed on the second interlayer insulating layer 105. The first connection line CL1 may be formed of the same material on the same layer as the low-potential power voltage line VSSL. For example, the first connection line CL1 may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

For example, one end of the first connection line CL1 may be connected to a link line, and the other end of the first connection line CL1 may be connected to the first electrostatic discharger 131. For example, when the link line is disposed on the gate insulating layer 103, one end of the first connection line CL1 may be electrically connected to the link line through a contact hole formed in the first interlayer insulating layer 104 and the second interlayer insulating layer 105.

The second connection line CL2 transmits a gate driving signal and may be referred to as “gate driving signal line”. The second connection line CL2 may be disposed between the plurality of first electrostatic dischargers 131 and the plurality of gate blocks GB. Also, the second connection line CL2 may be connected between the plurality of first electrostatic dischargers 131 and the plurality of pixel blocks PB. The second connection line CL2 may be connected to the first electrostatic discharger 131 and may extend in the column direction.

The second connection line CL2 may be disposed on the first planarization layer 107. The second connection line CL2 may be formed of the same material on the same layer as the metal layer ML. For example, the metal layer ML may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

For example, one end of the second connection line CL2 may be connected to the first electrostatic discharger 131, and the other end of the second connection line CL2 may be connected to the plurality of gate blocks GB or the plurality of pixel blocks PB. For example, one end of the second connection line CL2 may be electrically connected to the first electrostatic discharger 131 through a contact hole in the first planarization layer 107.

A gate driver disposed in a non-display area around a display apparatus results in an increase in size of a bezel corresponding to the size of the gate driver.

Thus, in the display apparatus 100 according to an example embodiment of the present disclosure, the gate driver is divided into the plurality of gate blocks GB and disposed in the display area AA. Therefore, the size of the non-display area NA on opposite lateral sides of the display panel PN can be minimized.

However, if the gate driver is disposed in the display area AA to reduce the size of the non-display area NA, there is no space to place an electrostatic discharger connected to the gate driver.

Thus, in the display apparatus 100 according to an example embodiment of the present disclosure, the opening 140 is disposed to expose an underlying layer of the constant voltage line VCL disposed in a power area of the non-display area NA. Also, the electrostatic discharger 130 is disposed in the opening 140. Therefore, the size of the non-display area NA on opposite lateral sides of the display panel PN can be minimized. Also, the electrostatic discharger 130 connected to the gate driver can be disposed. Accordingly, it is possible to possible to reduce a defect caused by static electricity while minimizing a bezel.

Further, if the electrostatic discharger is disposed outside an encapsulation unit, a defect, such as uniform corrosion, may occur in a reliability environment.

Thus, in the display apparatus 100 according to an example embodiment of the present disclosure, the electrostatic discharger 130 may be disposed in the area in which the encapsulation unit 120 is disposed. Therefore, it is possible to reduce a defect caused by static electricity while securing the reliability of the electrostatic discharger 130.

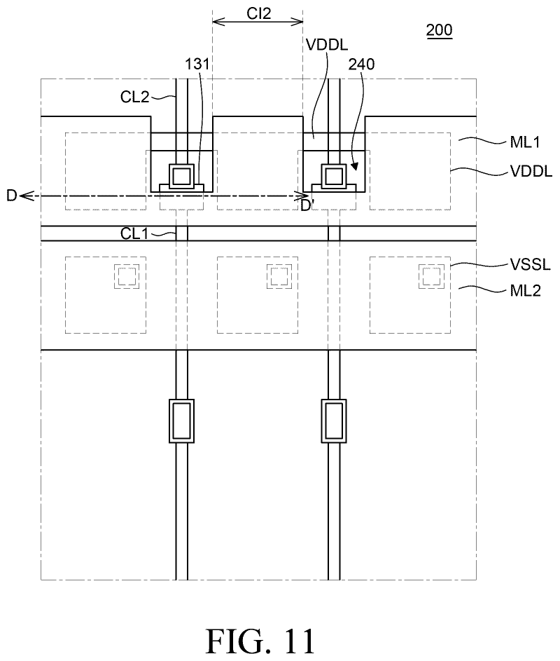

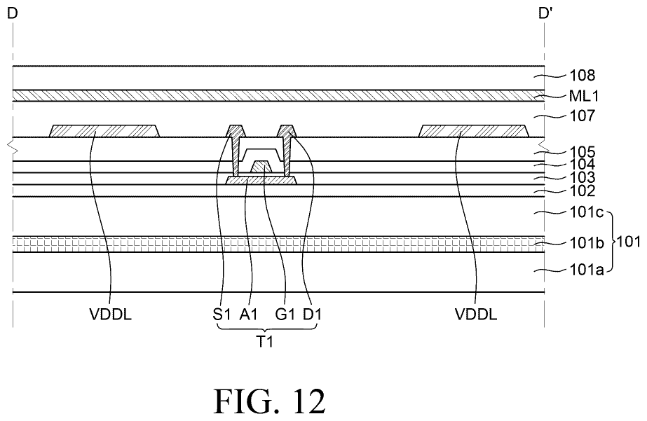

FIG. 11 is a plan view illustrating a part of a non-display area of a display apparatus according to another example embodiment of the present disclosure. FIG. 12 is a cross-sectional view taken along the line D-D′ of FIG. 11. A display apparatus 200 shown in FIG. 11 is substantially the same as the display apparatus 100 shown in FIG. 5 except a first metal layer ML1 and a second metal layer ML2. Therefore, redundant description thereof will be omitted.

Referring to FIG. 11 and FIG. 12, the high-potential power voltage line VDDL may extend in the row direction in the non-display area NA. The plurality of openings 140 may be spaced apart by a constant interval from each other on the high-potential power voltage line VDDL. For example, the plurality of openings 140 may be formed by opening one lower surface of the high-potential power voltage line VDDL. The plurality of first electrostatic dischargers 131 may be disposed in the plurality of openings 140, respectively. For example, the plurality of first electrostatic dischargers 131 may be disposed in the plurality of openings 140 disposed on the high-potential power voltage line VDDL. The plurality of first electrostatic dischargers 131 may be disposed to be spaced apart by a predetermined interval from the high-potential power voltage line VDDL.

The high-potential power voltage line VDDL may be disposed on the second interlayer insulating layer 105. The high-potential power voltage line VDDL may be formed of the same material on the same layer as the first source electrode S1 and the first drain electrode D1 of the first transistor T1. For example, the high-potential power voltage line VDDL may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The first metal layer ML1 may be disposed on the high-potential power voltage line VDDL.

The first metal layer ML1 may have a greater area than the high-potential power voltage line VDDL. The first metal layer ML1 may extend in the row direction so as to overlap the high-potential power voltage line VDDL. The first metal layer ML1 may be disposed to overlap, at least in part, the first electrostatic discharger 131. The first metal layer ML1 may be disposed to cover the upper portion of the first electrostatic discharger 131. For example, the first metal layer ML1 may be disposed on the first electrostatic discharger 131 so as to overlap the first electrostatic discharger 131 except a part thereof.

A plurality of second openings 240 for exposing an underlying layer may be disposed on the first metal layer ML1. For example, the plurality of second openings 240 may be disposed to be spaced apart by a constant interval CI2 from each other on the first metal layer ML1. The plurality of second openings 240 may be formed by opening one surface of the first metal layer ML1. For example, the plurality of second openings 240 may be disposed in an area corresponding to a part of the first electrostatic discharger 131 and a second connection electrode CE2. The plurality of second openings 240 may be formed by etching a part of the first metal layer ML1.

For example, the first metal layer ML1 may be disposed on the first planarization layer 107. The first metal layer ML1 may be formed of the same material on the same layer as the second connection electrode CE2. For example, the first metal layer ML1 may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The first metal layer ML1 may be connected to the high-potential power voltage line VDDL through an interconnection structure. For example, the first metal layer ML1 may be electrically connected to the high-potential power voltage line VDDL through a contact hole. That is, the first metal layer ML1 may be electrically connected to the high-potential power voltage line VDDL so as to be applied with a high-potential power voltage. Thus, the first metal layer ML1 may be applied with a high-potential power voltage and may serve as a high-potential power voltage line.

The low-potential power voltage line VSSL may be disposed in the row direction in the non-display area NA.

The low-potential power voltage line VSSL may be disposed as a plurality of island structures spaced apart from each other. The low-potential power voltage line VSSL may be disposed to be spaced apart from each other in the row direction. The low-potential power voltage line VSSL may be disposed to be spaced apart by a predetermined interval from and parallel to the high-potential power voltage line VDDL.

The low-potential power voltage line VSSL may be disposed on the second interlayer insulating layer 105. The low-potential power voltage line VSSL may be formed of the same material on the same layer as the high-potential power voltage line VDDL. For example, the low-potential power voltage line VSSL may be configured by a single layer of one of molybdenum (Mo), copper (Cu), titanium (Ti), aluminum (Al), chromium (Cr), gold (Au), nickel (Ni), neodymium (Nd), and an alloy thereof, or a multi-layer thereof.

The second metal layer ML2 may be disposed on the low-potential power voltage line VSSL.

The second metal layer ML2 may have a greater area than the low-potential power voltage line VSSL. The second metal layer ML2 may extend in the row direction so as to overlap the low-potential power voltage line VSSL. For example, the second metal layer ML2 may be disposed on the first planarization layer 107. The second metal layer ML2 may be formed of the same material on the same layer as the connection electrode CE. For example, the second metal layer ML2 may be configured by a single layer of one of molybdenum (Mo), copper (Cu), titanium (Ti), aluminum (Al), chromium (Cr), gold (Au), nickel (Ni), neodymium (Nd), or an alloy thereof, or a multi-layer thereof.

The second metal layer ML2 may be connected to the low-potential power voltage line VSSL through an interconnection structure. For example, the second metal layer ML2 may be electrically connected to the low-potential power voltage line VSSL through a contact hole. That is, the second metal layer ML2 may be electrically connected to the low-potential power voltage line VSSL so as to be applied with a low-potential power voltage. Thus, the second metal layer ML2 may be applied with a low-potential power voltage and may serve as a low-potential power voltage line.

The example embodiments of the present disclosure can also be described as follows:

A display apparatus according to an example embodiment of the present disclosure includes a substrate including a substrate including a display area in which a plurality of sub-pixels are disposed and a non-display area adjacent to the display area, a constant voltage line disposed in the non-display area and including a plurality of openings and a plurality of electrostatic dischargers disposed in the plurality of openings.

The display apparatus may further include an encapsulation unit disposed on the substrate and covering at least a part of the display area and the non-display area, wherein the plurality of electrostatic dischargers are disposed inside an end of the encapsulation unit.

The constant voltage line may be configured to provide a constant voltage to the plurality of sub-pixels, and the constant voltage may be one of a low-potential power voltage, a reference voltage, or a high-potential power voltage.

The display apparatus may further include at least one flexible substrate connected to a side portion of the non-display area, the plurality of electrostatic dischargers are disposed in the side portion of the non-display area connected to the flexible substrate.

The display apparatus may further include a gate driver dispersed in the display area on the substrate and configured to output a gate signal to the plurality of sub-pixels, the plurality of electrostatic dischargers are disposed corresponding to an area in which the gate driver is disposed.

The display apparatus may further include a plurality of gate driving signal lines disposed on the substrate and configured to supply a gate driving signal to the gate driver, the plurality of electrostatic dischargers are each connected to a gate driving signal line of the plurality of gate driving signal lines.

The plurality of gate driving signal lines may include at least one of a clock signal line, a start signal line, a gate high voltage line, or a gate low voltage line.

The display apparatus may further include a planarization layer disposed on the constant voltage line and the plurality of electrostatic dischargers and a metal layer disposed on the planarization layer.

A display apparatus according to another example embodiment of the present disclosure includes a substrate including a display area and a non-display area adjacent to the display area, the display area including a plurality of sub-pixels, a first constant voltage line in the non-display area and including a plurality of first openings, a plurality of island structures in the non-display area, each island structure separated from the first constant voltage line, a plurality of first electrostatic dischargers in the plurality of first openings and a plurality of first connection lines each connected to a first electrostatic discharger, and each extending between two island structures of the plurality of island structures.

Each first connection line of the plurality of first connection lines may be connected to a first electrostatic discharger and a flexible film, the flexible film coupled to the non-display area, and the non-display area between the flexible film and the display area.

The display apparatus may include a metal layer over the plurality of island structures, each island structure connected to the metal layer through an interconnection structure.

The metal layer and the plurality of island structures may be configured to be a second constant voltage line of a different voltage level from the first constant voltage line.

The display area may include one or more gate blocks and one or more pixel blocks, and the display apparatus further comprises a plurality of second connection lines each connected between a first electrostatic discharger of the plurality of first electrostatic dischargers and one of the one or more gate blocks or one of the one or more pixel blocks.

The plurality of second connection lines may be on a same layer as the metal layer.

A pixel block includes multiple sub-pixels of different colors, and each of the multiple sub-pixels may be connected to a second connection line of the plurality of second connection lines.

The first constant voltage line and the plurality of islands structures may be on a same layer.

A width of a gate block may be substantially same as a width of a first opening in the first constant voltage line.

The first electrostatic discharger may include a first transistor having a first source electrode, a first drain electrode, and a first gate, the first source electrode and the first drain electrode are on a same level as the first constant voltage line.

The display apparatus may include an encapsulation layer overlapping the display area and at least a part of the non-display area, the encapsulation layer overlapping the first constant voltage line, the plurality of first electrostatic dischargers, and the plurality of island structures.

The first constant voltage line may include a comb shape, and a first opening including at least one side that is not surrounded by the first constant voltage line.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

Described embodiments of the subject matter can include one or more features, alone or in combination. For example, in an embodiment, a display apparatus includes a substrate including a display area in which a plurality of sub-pixels are disposed and a non-display area adjacent to the display area; a constant voltage line disposed in the non-display area and including a plurality of openings; and a plurality of electrostatic dischargers disposed in the plurality of openings.

The foregoing and other described embodiments can each, in some implementations, include one or more of the following features.

A first feature, combinable with any of the preceding or following features, specifies that the plurality of electrostatic dischargers each includes: a first transistor connected between the gate driving signal line and a first voltage line; and a second transistor connected between the gate driving signal line and a second voltage line. A second feature, combinable with any of the preceding or following features, specifies that a gate electrode and a source electrode of the first transistor are connected to the gate driving signal line and a drain electrode of the first transistor is connected to the first voltage line, and a gate electrode and a source electrode of the second transistor are connected to the second voltage line and a drain electrode of the second transistor is connected to the gate driving signal line

A third feature, combinable with any of the preceding or following features, specifies the first voltage line is at least one of a low-potential voltage line to be applied with a low-potential voltage or a gate low signal line to be applied with a gate low signal, and the second voltage line is at least one of a high-potential voltage line to be applied with a high-potential voltage or a gate high signal line to be applied with a gate high signal.

In an embodiment, a display apparatus includes a substrate including a display area and a non-display area adjacent to the display area, the display area including a plurality of pixel blocks and one or more gate blocks; a plurality of sub-pixels disposed on the plurality of pixel blocks, the plurality of pixel blocks including a first pixel block and a second pixel block each including one or more sub-pixels of the plurality of sub-pixels; a first divided gate driver disposed on a first gate block of the one or more gate blocks; a first electrostatic discharger disposed on the non-display area; and a first gate driving line connected to the first divided gate driver and the first electrostatic discharger.

A fourth feature, combinable with any of the preceding or following features, specifies the first gate block is positioned between the first pixel block and the second pixel blocks.

A fifth feature, combinable with any of the preceding or following features, specifies that the plurality of pixel blocks includes a third pixel block, and the one or more gate blocks include a second gate block positioned between the second pixel block and the third pixel block, and specifies that the display apparatus further includes a second divided gate driver disposed on the second gate block; a second electrostatic discharger disposed on the non-display area and spaced apart from the first electrostatic discharger; and a second gate driving line connected to the second divided gate driver and the second electrostatic discharger.

A sixth feature, combinable with any of the preceding or following features, specifies that the first electrostatic discharger corresponds in position to the first divided gate driver, and the second electrostatic discharger corresponds in position to the second divided gate driver.

A seventh feature, combinable with any of the preceding or following features, specifies that the display apparatus further includes a voltage line on the non-display area, wherein the first electrostatic discharger is in a first opening in the voltage line and the second electrostatic discharger is in a second opening in the voltage line, the second opening spaced apart from the first opening.

In an embodiment, a display apparatus includes a substrate including a display area and a non-display area adjacent to the display area; a plurality of sub-pixels disposed on the display area; at least two divided gate drivers disposed on the display area, the at least two divided gate drivers spaced apart from one another; at least two electrostatic dischargers disposed on a first portion of the non-display area, the at least two electrostatic dischargers spaced apart from one another; and a plurality gate driving lines, each electrostatic discharger connected to a divided gate driver through a gate driving line of the plurality gate driving lines.

An eighth feature, combinable with any of the preceding or following features, specifies that the display apparatus further includes a flexible film, the flexible film connected to a first side of the first portion of the non-display area, a second side of the first portion of the non-display area adjacent to the display area, the first side opposite to the second side of the first portion of the non-display area.

In an embodiment, a display apparatus includes a substrate including a display area and a non-display area adjacent to the display area, the display area including a plurality of sub-pixels; a first constant voltage line in the non-display area and including a plurality of first openings; a plurality of island structures in the non-display area, each island structure separated from the first constant voltage line; a plurality of first electrostatic dischargers in the plurality of first openings; and a plurality of first connection lines each connected to a first electrostatic discharger, and each extending between two island structures of the plurality of island structures.

An ninth feature, combinable with any of the preceding or following features, specifies that each first connection line of the plurality of first connection lines is connected to a first electrostatic discharger and a flexible film, the flexible film coupled to the non-display area, and the non-display area between the flexible film and the display area.

A tenth feature, combinable with any of the preceding or following features, specifies that the display apparatus further includes a metal layer over the plurality of island structures, each island structure connected to the metal layer through an interconnection structure.

An eleventh feature, combinable with any of the preceding or following features, specifies that the metal layer and the plurality of island structures are configured to be a second constant voltage line of a different voltage level from the first constant voltage line.

A twelfth feature, combinable with any of the preceding or following features, specifies that the display area includes one or more gate blocks and one or more pixel blocks, and the display apparatus further includes a plurality of second connection lines each connected between a first electrostatic discharger of the plurality of first electrostatic dischargers and one of the one or more gate blocks or one of the one or more pixel blocks.

A thirteenth feature, combinable with any of the preceding or following features, specifies that the plurality of second connection lines are on a same layer as the metal layer.

A fourteenth feature, combinable with any of the preceding or following features, specifies that a pixel block includes multiple sub-pixels of different colors, and each of the multiple sub-pixels is connected to a second connection line of the plurality of second connection lines.

A fifteenth feature, combinable with any of the preceding or following features, specifies that the metal layer does not overlap with each of the plurality of first electrostatic dischargers.

A sixteenth feature, combinable with any of the preceding or following features, specifies that the first constant voltage line and the plurality of islands structures are on a same layer.

A seventeenth feature, combinable with any of the preceding or following features, specifies that a width of a gate block is substantially same as a width of a first opening in the first constant voltage line.

An eighteenth feature, combinable with any of the preceding or following features, specifies that the first electrostatic discharger includes a first transistor having a first source electrode, a first drain electrode, and a first gate, the first source electrode and the first drain electrode are on a same level as the first constant voltage line.

An nineteenth feature, combinable with any of the preceding or following features, specifies that the display apparatus further includes an encapsulation layer overlapping the display area and at least a part of the non-display area, the encapsulation layer overlapping the first constant voltage line, the plurality of first electrostatic dischargers, and the plurality of island structures.

A twentieth feature, combinable with any of the preceding or following features, specifies that the first constant voltage line includes a comb shape, and a first opening including at least one side that is not surrounded by the first constant voltage line.

In an embodiment, a display apparatus includes a substrate including a display area and a non-display area adjacent to the display area, the display area including a plurality of sub-pixels; a plurality of first island structures in the non-display area, each first island structure including a first openings; a plurality of second island structures in the non-display area, each second island structure separated from each of the plurality of first island structures; a plurality of first electrostatic dischargers each in a first opening of a first island structure of the plurality of first island structures; and a plurality of first connection lines each connected to a first electrostatic discharger, and each extending between two second island structures of the plurality of second island structures.

A twenty first feature, combinable with any of the preceding or following features, specifies that the display apparatus further includes a second metal pattern over the plurality of second island structures, each second island structure connected to the second metal pattern through an interconnection structure.

A twenty second feature, combinable with any of the preceding or following features, specifies that the first metal pattern and the second metal pattern are on a same level as one another.

A twenty third feature, combinable with any of the preceding or following features, specifies that the first metal pattern and the first plurality of island structures are configured to be a first constant voltage line, the second metal pattern and the second plurality of island structures are configured to be a second constant voltage line of a different voltage level from the first constant voltage line.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a display area in which a plurality of sub-pixels are disposed and a non-display area adjacent to the display area;
a constant voltage line disposed in the non-display area and including a plurality of openings; and
a plurality of electrostatic dischargers disposed in the plurality of openings.

2. The display apparatus according to claim 1, further comprising:
an encapsulation unit disposed on the substrate and covering at least a part of the display area and the non-display area,
wherein the plurality of electrostatic dischargers are disposed inside an end of the encapsulation unit.

3. The display apparatus according to claim 1, wherein the constant voltage line is configured to provide a constant voltage to the plurality of sub-pixels, and the constant voltage is one of a low-potential power voltage, a reference voltage, or a high-potential power voltage.

4. The display apparatus according to claim 1, further comprising:
at least one flexible substrate connected to a side portion of the non-display area,
wherein the plurality of electrostatic dischargers are disposed in the side portion of the non-display area connected to the flexible substrate.

5. The display apparatus according to claim 1, further comprising:
a gate driver dispersed in the display area on the substrate and configured to output a gate signal to the plurality of sub-pixels,
wherein the plurality of electrostatic dischargers are disposed corresponding to an area in which the gate driver is disposed.

6. The display apparatus according to claim 5, further comprising:
a plurality of gate driving signal lines disposed on the substrate and configured to supply a gate driving signal to the gate driver,
wherein the plurality of electrostatic dischargers are each connected to a gate driving signal line of the plurality of gate driving signal lines.

7. The display apparatus according to claim 6, wherein the plurality of gate driving signal lines includes at least one of a clock signal line, a start signal line, a gate high voltage line, or a gate low voltage line.

8. The display apparatus according to claim 1, further comprising:
a planarization layer disposed on the constant voltage line and the plurality of electrostatic dischargers; and
a metal layer disposed on the planarization layer.

9. A display apparatus, comprising:
a substrate including a display area and a non-display area adjacent to the display area, the display area including a plurality of sub-pixels;
a first constant voltage line in the non-display area and including a plurality of first openings;
a plurality of island structures in the non-display area, each island structure separated from the first constant voltage line;
a plurality of first electrostatic dischargers in the plurality of first openings; and
a plurality of first connection lines each connected to a first electrostatic discharger, and each extending between two island structures of the plurality of island structures.

10. The display apparatus of claim 9, wherein each first connection line of the plurality of first connection lines is connected to a first electrostatic discharger and a flexible film, the flexible film coupled to the non-display area, and the non-display area between the flexible film and the display area.

11. The display apparatus of claim 9, comprising a metal layer over the plurality of island structures, each island structure connected to the metal layer through an interconnection structure.

12. The display apparatus of claim 11, wherein the metal layer and the plurality of island structures are configured to be a second constant voltage line of a different voltage level from the first constant voltage line.

13. The display apparatus of claim 11, wherein the display area includes one or more gate blocks and one or more pixel blocks, and
the display apparatus further comprises a plurality of second connection lines each connected between a first electrostatic discharger of the plurality of first electrostatic dischargers and one of the one or more gate blocks or one of the one or more pixel blocks.

14. The display apparatus of claim 13, wherein the plurality of second connection lines are on a same layer as the metal layer.

15. The display apparatus of claim 13, wherein a pixel block includes multiple sub-pixels of different colors, and each of the multiple sub-pixels is connected to a second connection line of the plurality of second connection lines.

16. The display apparatus of claim 9, wherein the first constant voltage line and the plurality of islands structures are on a same layer.

17. The display apparatus of claim 14, wherein a width of a gate block is substantially same as a width of a first opening in the first constant voltage line.

18. The display apparatus of claim 9, wherein the first electrostatic discharger includes a first transistor having a first source electrode, a first drain electrode, and a first gate, the first source electrode and the first drain electrode are on a same level as the first constant voltage line.

19. The display apparatus of claim 9, comprising an encapsulation layer overlapping the display area and at least a part of the non-display area, the encapsulation layer overlapping the first constant voltage line, the plurality of first electrostatic dischargers, and the plurality of island structures.

20. The display apparatus of claim 9, wherein the first constant voltage line includes a comb shape, and a first opening includes at least one side that is not surrounded by the first constant voltage line.
